(19) United States
(12) Patent Application Publication
(10) Pub. No.: US 2016/0141187 A1
(43) Pub. Date: May 19, 2016

(54) METHOD OF MANUFACTURING AN INTEGRATED CIRCUIT WITH IMPRINT, INTEGRATED CIRCUIT WITH IMPRINT, DEVICE FOR FORMING AN INTEGRATED CIRCUIT WITH IMPRINT AND VERIFICATION SYSTEM FOR AN INTEGRATED CIRCUIT WITH IMPRINT

(71) Applicant: Infineon Technologies AG, Neubiberg (DE)

(72) Inventors: Carlo Baterna Marbella, Singapore (SG); Wai Loon Kwan, Melaka (MY); Min King Chai, Melaka (MY); Veng Leong Tham, Singapore (SG)

(21) Appl. No.: 14/541,163

(22) Filed: Nov. 14, 2014

(51) Int. Cl. H01L 21/56; H01L 23/42; B29C 51/26; G07C 11/00; B29C 51/12; H01L 23/31; H01L 21/67

(52) U.S. Cl. CPC H01L 21/565; H01L 23/3107; H01L 23/42; H01L 21/67126; G07C 11/00; B29C 51/12; B29C 51/264; B29K 2101/00

(57) ABSTRACT

According to various embodiments, a method of manufacturing an integrated circuit may include providing a film structure having at least one of at least one recess or at least one protrusion, and carrying out a film assisted molding process using the film structure to mold an electronic circuit, thereby forming a molding structure including a surface pattern in accordance with the film structure.

### TECHNICAL FIELD

Various embodiments relate to an integrated circuit, a method of manufacturing the same, a device for forming the same and a verification system for an integrated circuit.

### BACKGROUND

Counterfeiting of semiconductor components is a growing trend. This may pose risks and impacts, for example to the public and companies, such as risk to health, critical infrastructure and economy, financial losses, reputation damage, and product liability.

Presently, internal control measures remain the first layer of defence, for example, with companies establishing an anti-counterfeit program and strategy which may include prevention, detection and response.

Further, thermal effects of a package may be an issue. Current approaches of thermal enhancement (for example heat spreader) within a package generally means additional cost due to the heat spreader attachment process step during assembly, more space required on the substrate, for example laminate to attach the heat spreader, meaning that the thermal element requires additional substrate space to attach to, and where there are wirebonds, there may not be enough space to directly attach the heat spreader to the chip, such that the heat spreader is usually not touching the chip, meaning that the thermal element does not directly contact the chip.

### SUMMARY

According to an embodiment, a method of manufacturing an integrated circuit is provided. The method may include providing a film structure having at least one of at least one recess or at least one protrusion, and carrying out a film assisted molding process using the film structure to mold an electronic circuit, thereby forming a molding structure including a surface pattern in accordance with the film structure

According to an embodiment, an integrated circuit is provided. The integrated circuit may include an electronic circuit, and a mold encapsulating the electronic circuit, wherein the mold comprises an outer surface pattern imprinted into the mold.

According to an embodiment, a device for forming an integrated circuit is provided. The device may include a film structure having at least one of at least one recess or at least one protrusion, and an apparatus for forming an integrated circuit, the apparatus configured to carry out a film assisted molding process using the film structure to mold an electronic circuit, thereby forming a molding structure including a surface pattern in accordance with the film structure.

According to an embodiment, a verification system for an integrated circuit is provided. The verification system may include a database comprising a plurality of different coded patterns, a reader for reading a mold of an integrated circuit to determine presence of a surface pattern on the mold, and a verification circuit configured to verify the surface pattern, if present on the mold, against the plurality of different coded patterns in the database, wherein the verification circuit is further configured to generate a positive indication signal if the surface pattern is verified to be determined from the plurality of different coded patterns, and to generate a negative indication signal if the surface pattern is verified to be not determined from the plurality of different coded patterns or if a surface pattern is not present on the mold.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a flow chart illustrating a method of manufacturing an integrated circuit, according to various embodiments.

FIG. 1B shows a schematic cross-sectional view of an integrated circuit, according to various embodiments.

FIG. 1C shows a schematic cross-sectional view of device for forming an integrated circuit, according to various embodiments.

FIG. 2A shows a schematic view of a conventional method for manufacturing an integrated circuit.

FIG. 2B shows a schematic view of a method for manufacturing an integrated circuit, according to various embodiments.

FIG. 3 shows a schematic view of a method for manufacturing an integrated circuit, according to various embodiments.

FIGS. 4A and 4B show schematic views of different methods for forming a film structure, according to various embodiments.

FIGS. 5A and 5B show images of examples of film structures, according to various embodiments.

FIG. 6 shows a schematic view of a system-level procedure, according to various embodiments.

FIG. 7 shows a schematic view of a method for manufacturing an integrated circuit, according to various embodiments.

FIG. 8 shows a schematic cross-sectional view of an integrated circuit with a heat dissipating element, according to various embodiments.

FIG. 9 shows a schematic view of a method for manufacturing an integrated circuit, according to various embodiments.

FIGS. 10A and 10B show schematic views of different methods for forming a heat dissipation element to a film, according to various embodiments.

FIGS. 11A and 11B show schematic views of different integrated circuits that may be formed, according to various embodiments.

FIGS. 12A and 12B show schematic views of different integrated circuits that may be formed, according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

In the context of various embodiments, the articles “a”, “an” and “the” as used with regard to a feature or element include a reference to one or more of the features or elements.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

In the context of various embodiments, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a ‘circuit’ in accordance with an alternative embodiment.

Various embodiments may provide an integrated circuit package with imprinted traceability and embedded heat dissipation elements with methods of manufacturing and verification system.

Various embodiments may provide variable imprinting of integrated circuits (e.g. semiconductor packages) for anti-counterfeit applications or purposes.

Various embodiments may enable a physical, highly variable and coded imprint mark (or surface pattern) on the mold or molding structure of a semiconductor package or an integrated circuit. By “physical”, it is meant that the imprint may be physically part of the mold (e.g. surface topography), and not a separate add-on material. Since the imprint, which may act as a counterfeit mark, is imprinted on the mold and manifests as a unique topography (e.g. surface height differences), it may be more difficult to re-create, compared to conventional surface material subtractive marking processes such as laser marking, which is a form of heat ablation. Various embodiments may enable high variability/high uniqueness for the marks, meaning that there may be high variation of the mark design, creating high uniqueness between units, or between lots, and therefore it may be more difficult to counterfeit or replicate. Further, the imprint may be “coded”, and may be part of a system-level verification, which may allow an additional layer of uniqueness verifiability against a secured code database.

Various embodiments may create “layers” with respective target purposes. For example, various embodiments may provide “Layer 1”, which may be a physical imprint offering a 1st layer of protection. This may provide a quick differentiation method against counterfeits without any physical imprint. This may allow a fast check and does not need to log-in to a code verification system. Further, various embodiments may provide “Layer 2”, which may be a verification system for imprinted “Code” and product mark. The verification system may create higher anti-counterfeit robustness. The imprinted code and product mark combination may enable verification, for example to a system-level counterfeit code database or server.

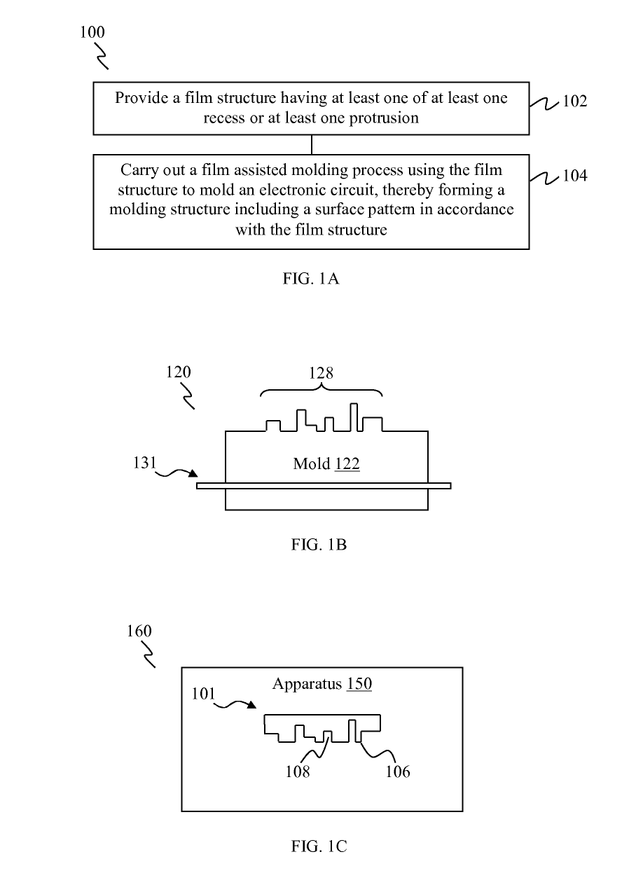

FIG. 1A shows a flow chart illustrating a method 100 of manufacturing an integrated circuit, according to various embodiments.

At 102, a film structure having at least one of at least one recess or at least one protrusion is provided. This may mean that the film structure may have one or more recesses (or troughs, depressions) and/or one or more protrusions (or peaks).

At 104, a film assisted molding process is carried out using the film structure to mold an electronic circuit, thereby forming a molding structure including a surface pattern in accordance with the film structure. In this way, the features of the film structure, meaning the at least one recess or at least one protrusion, may be transferred to the molding structure. As the surface pattern is formed on the molding structure during molding, there is no or minimal loss of material of the molding structure after the molding process.

In various embodiments, the surface pattern may form part of the molding structure, e.g. being physically part of the molding structure.

In various embodiments, the at least one of at least one recess or at least one protrusion of the film structure may face the mold during the film assisted molding process.

In various embodiments, a film may be patterned to form the film structure. As a non-limiting example, the film may be laser processed (i.e. using a laser) to pattern the film.

In various embodiments, a mold pattern may be determined (or generated) from a plurality of different coded patterns provided in a database, and the film may be patterned in accordance with the determined mold pattern. In various embodiments, the mold pattern may be or may include one of the coded patterns or may include a combination of two or more coded patterns.

In various embodiments, the method may further include placing one or more additional elements, such as thermally conductive material, over a surface of a film, and transferring the thermally conductive material into the molding structure. The thermally conductive material may be transferred into the molding structure during the film assisted molding process. In various embodiments, the thermally conductive material may be pressed or embedded into the mold material to form the molding structure. In various embodiments, the one or more additional elements may also include an electrical component, e.g., a passive electrical component.

In various embodiments, the thermally conductive material may be embedded at least partially in the molding structure.

In various embodiments, at least one surface of the thermally conductive material formed in the molding structure may be exposed. In various embodiments, at least one surface of the thermally conductive material formed in the molding structure may be coplanar with the surface of the molding structure.

While the method described above is illustrated and described as a series of steps or events, it will be appreciated that any ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

FIG. 1B shows a schematic cross-sectional view of an integrated circuit 120, according to various embodiments. The integrated circuit 120 includes an electronic circuit 131, and a mold 122 encapsulating the electronic circuit 131, wherein the mold 122 includes an outer surface pattern 128 imprinted into the mold 122.

In various embodiments, the outer surface pattern 128 may have at least one of at least one recess or at least one protrusion.

In various embodiments, the integrated circuit 120 may further include a thermally conductive material embedded into the mold 122.

In various embodiments, at least one surface of the thermally conductive material formed in the mold 122 may be exposed.

FIG. 1C shows a schematic cross-sectional view of a device 160 for forming an integrated circuit, according to various embodiments. The device 160 includes a film structure 101 having at least one of at least one recess 108 or at least one protrusion 106, and an apparatus 150 for forming an integrated circuit, the apparatus 150 configured to carry out a film assisted molding process using the film structure 101 to mold an electronic circuit, thereby forming a molding structure including a surface pattern in accordance with the film structure 101.

In various embodiments, the device 160 may further include a pattern forming device configured to pattern a film to form the film structure 101. In various embodiments, the pattern forming device may include a laser.

In various embodiments, the device 160 may further include a database including a plurality of different coded patterns, and a circuit for determining (or generating) a mold pattern from the plurality of different coded patterns, wherein the pattern forming device may be configured to pattern the film in accordance with the determined mold pattern.

In various embodiments, the device 160 may further include a film having a thermally conductive material over a surface of the film, wherein the apparatus 150 may be further configured to transfer the thermally conductive material into the molding structure. In various embodiments, the apparatus 150 may be configured to press the thermally conductive material into the mold material to form the molding structure.

In various embodiments, at least one surface of the thermally conductive material formed in the molding structure may be exposed.

In the context of various embodiments, the term “integrated circuit” may refer to a semiconductor package.

In the context of various embodiments, the thermally conductive material may act as a heat sink element, a heat spreader, or a heat dissipation element.

In the context of various embodiments, the thermally conductive material may include a metal. Examples of the metal include but not limited to copper (Cu) and aluminium (Al).

In the context of various embodiments, the thermally conductive material may be formed by a metal block. This may mean that the thermally conductive material may be a metal block.

In the context of various embodiments, the thermally conductive material may have a surface marking. The surface marking may be a package marking, for example which may be used to identify the integrated circuit. The surface marking may be provided to the thermally conductive material prior to molding of the integrated circuit.

In the context of various embodiments, the thermally conductive material may not be in contact (e.g. may not be in direct contact) with the electronic circuit (e.g. 131) or a substrate of the electronic circuit (e.g. 131). This may mean that there may be no contact with the die, wire, leadframe or substrate of the electronic circuit. In this way, the thermally conductive material may be a floating or suspended thermally conductive material.

In the context of various embodiments, the entire thermally conductive material may be arranged spaced apart from the electronic circuit (e.g. 131) or a substrate of the electronic circuit (e.g. 131). In this way, the thermally conductive material may be a floating or suspended thermally conductive material.

As described above, the surface pattern may include at least one surface topographical feature. This may mean a feature having a height that may be different from another part of the surface pattern. As a result, there may be surface height differences in the surface pattern of the mold or molding structure of the resulting integrated circuit.

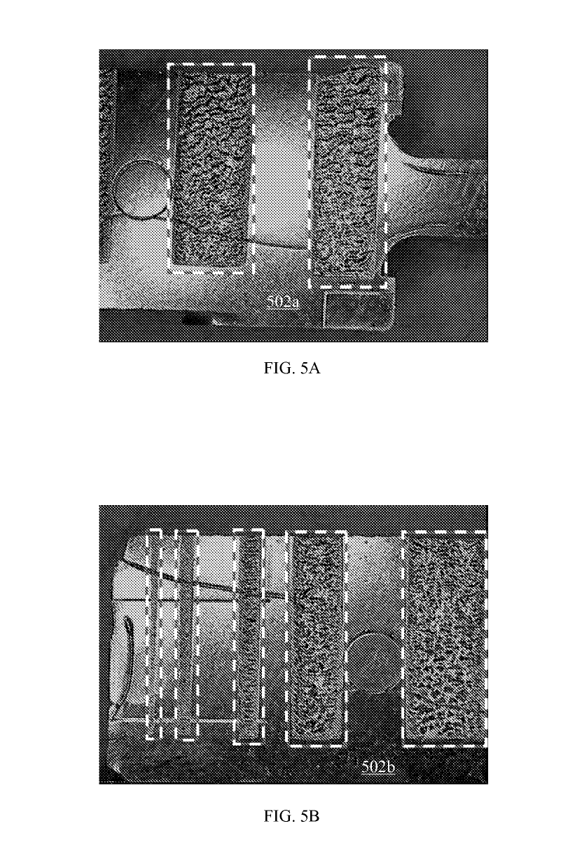

In the context of various embodiments, the surface pattern may include at least one of a dot, a linear line, a curved line, a barcode, a geometrical shape, a number, an alphabetical letter, a character, a symbol, a morphological structure (e.g., a rough surface) or a topographical structure. In various embodiments, the surface pattern may include a combination of the above-mentioned features or characteristics (e.g., shape and morphological structure), as may be described later with reference to FIGS. 5A and 5B.

In the context of various embodiments, the surface pattern may include a two-dimensional (2D) structure or a three-dimensional (3D) structure.

In the context of various embodiments, the surface pattern may include undulations.

In the context of various embodiments, the surface pattern may be pre-determined (or generated) from a plurality of different coded patterns provided in a database.

In the context of various embodiments, the term “database” may include a database stored in a memory of a device (e.g. 160), or may be a server-based database, or may be a cloud-based database.

It should be appreciated that descriptions in the context of the method 100 may be correspondigly applicable also in the context of the integrated circuit 120 and the device 160 and vice versa.

Various embodiments may also provide a verification system for an integrated circuit, the system including a database having a plurality of different coded patterns, a reader for reading a mold of an integrated circuit to determine presence of a surface pattern on the mold, and a verification circuit configured to verify the surface pattern, if present on the mold, against the plurality of different coded patterns in the database, wherein the verification circuit is further configured to generate a positive indication signal if the surface pattern is verified to be determined from the plurality of different coded patterns, and to generate a negative indication signal if the surface pattern is verified to be not determined from the plurality of different coded patterns or if a surface pattern is not present on the mold.

Various embodiments may provide a “2 levels” approach: the component-level and the system-level, where the system-level may be an additional “built on top” or “dependent” to the component level.

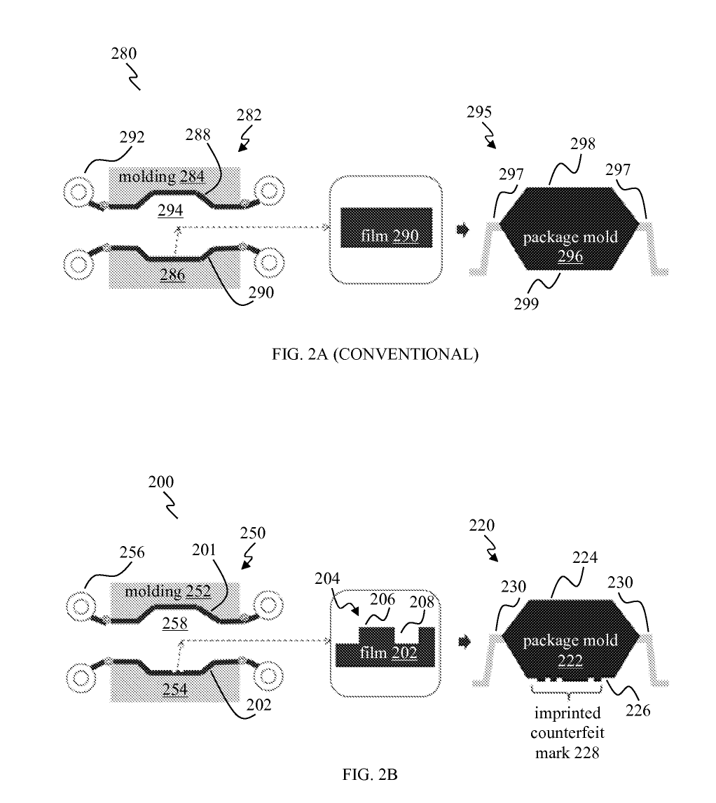

At the component level, there may be creation of (high variable) imprint or surface pattern on one or more regions of the package mold of an integrated circuit (e.g. a semiconductor package). FIG. 2A shows a schematic view of a conventional method 280 for manufacturing an integrated circuit (e.g. a semiconductor package), while FIG. 2B shows a schematic view of a method 200 for manufacturing integrated circuit (e.g. a semiconductor package), according to various embodiments, illustrating “component” level counterfeit code or imprint mark creation.

Referring to FIG. 2A, a package mold tool 282 may be used, which may include a molding housing including an upper molding portion 284 and a lower molding portion 286. A pair of films may be provided to the package mold tool 282, including an upper film 288 provided to the upper molding portion 284 and a lower film 290 provided to the lower molding portion 286. The package mold tool 282 may include a transportation system, including a plurality of rollers, for example as represented by 292 for one roller for moving the films 288, 290. Each of the films 288, 290 has uniform and planar surfaces. During manufaturing, an electronic circuit (not shown) may be provided in between the upper molding portion 284 and the lower molding portion 286, which may then be moved towards each other to define a cavity or chamber 294 and secure the electronic circuit in the cavity 294. The cavity 294 may be sealed and a molding material (not shown) may then be provided within the cavity 294. The molding material may be in contact with the films 288, 290. The molding material may then be processed, for example heated and cured to form a mold encapsulating the electronic circuit. As a result, an integrated circuit 295 may be formed, with a package mold 296 encapsulating the electronic circuit with its leadframe 297 exposed or protruding out of the package mold 296. As shown in FIG. 2A, the package mold 296 has flat, planar surfaces 298, 299, conforming to the surface shapes of the films 288, 290.

Referring to FIG. 2B, a package mold tool or apparatus 250 may be used, which may include a molding housing including an upper molding portion 252 and a lower molding portion 254. A pair of films may be provided to the package mold tool 250, including an upper film 201 provided to the upper molding portion 252 and a lower film 202 provided to the lower molding portion 254. The package mold tool 250 may include a transportation system, including a plurality of rollers, for example as represented by 256 for one roller for moving the films 201, 202. As shown in FIG. 2B, the lower film 202 may be a film structure having at least one protrusion 206 and/or at least one recess 208 formed on its side facing into the cavity 258 which may be formed between the upper molding portion 252 and the lower molding portion 254. During manufaturing, an electronic circuit (not shown) may be provided in between the upper molding portion 252 and the lower molding portion 254, which may then be moved towards each other to define the cavity or chamber 258 and secure the electronic circuit in the cavity 258. The cavity 258 may be sealed and a molding material (not shown) may then be provided within the cavity 258. The molding material may be in contact with the films 201, 202. The molding material may then be processed, for example heated and cured to form a mold encapsulating the electronic circuit. As a result, an integrated circuit (e.g. a semiconductor package) 220 may be formed, with a package mold or molding structure 222 encapsulating the electronic circuit with its leadframe 230 exposed or protruding out of the package mold 222. As shown in FIG. 2B, the package mold 222 may have a flat, planar surface 224 conforming to the surface shape of the film 201, and an opposite surface 226 having an imprint (imprinted mark) or surface pattern 228 formed on the bottom side of the mold 222, conforming to the surface shape of the film 202. Therefore, the film structure 202 having the film pattern 204 with at least one protrusion 206 and/or at least one recess 208 may act as a template for forming the surface pattern 228 on the mold or molding structure 222. It should be appreciated that a pattern with at least one protrusion and/or at least one recess may be provided to the upper film 201, alternative to or in addition to, the film pattern 204 of the lower film 202.

In various embodiments, the imprint 228 may have a positive height, meaning that the imprint may be higher than the general or major package mold surface. In various embodiments, the imprint 228 may also have a combination of positive and negative heights, where some imprints may have simple “undulations”. e.g. an artifact of the laser burn on the plastic film (e.g. 202) used. It should be appreciated that the method of various embodiments is not a substractive process, for example using laser on mold after the mold process, but an “imprint” at mold during the mold process.

The imprint 228 may be highly variable, for example the imprint 228 may change between units, or lots, or other means of groups. This may be carried out, for example by changing the film pattern 204 provided to the film(s) 201, 202 for molding. As non-limiting examples, the imprint or surface pattern 228 formed on the package mold 222 may include one or more sets of dots, lines, curves, or combinations at different locations on the mold surface, e.g. on the bottom, side or top of the package 220.

In various embodiments, the imprint 228 may include a “code”, which for example may be one or more symbols or a set of symbols, as well as their corresponding locations on the mold 222. Further, the imprint or code 228 may also include a unique created surface topology of the symbols, which may be an artifact of the lasered film. This may provide a “high magnification code” that exists within a “low magnification code”. Nevertheless, it should be appreciated that the code may be the variation of symbols or set of symbols and/or their placement/locations, and not necessarily the surface topology.

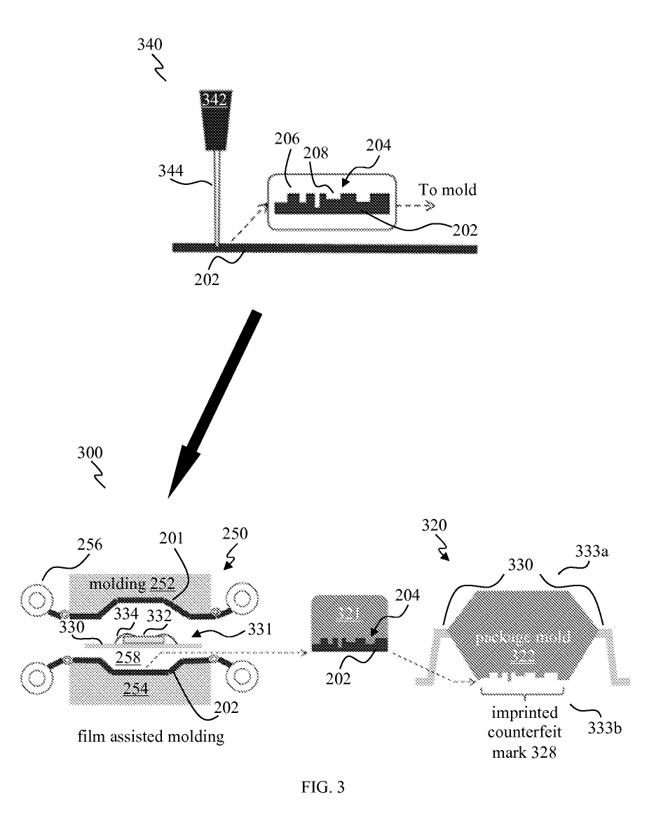

As a non-limiting example, one method of creating an imprint on the molding structure of an integrated circuit may be as applied to a film assisted molding of a package. FIG. 3 shows a schematic view of a method for manufacturing an integrated circuit, according to various embodiments, illustrating “component” level code placement to film and film-assisted molding during package assembly. The method may result in an integrated circuit or semiconductor package with an imprinted counterfeit surface pattern or code.

As shown in FIG. 3, the method may include a pre-molding procedure 340, where a film 202 may be pre-processed, before molding. The procedure 340 may correspond to code creation and placement to film. A film pattern, corresponding to the intended imprinted mark, may be created by removing material on a film 202, for example by using a laser 342 for creating the intended counterfeit-mark or intended imprint design. The beam or radiation 344 from the laser 342 may be directed to the film 202 to remove materials from the film 202, by ablation. The film pattern or mark design formed on the film 202 may include a “compensation” to counter expected film shrinkage, expansion or stretching in the later molding (and post-mold curing) process.

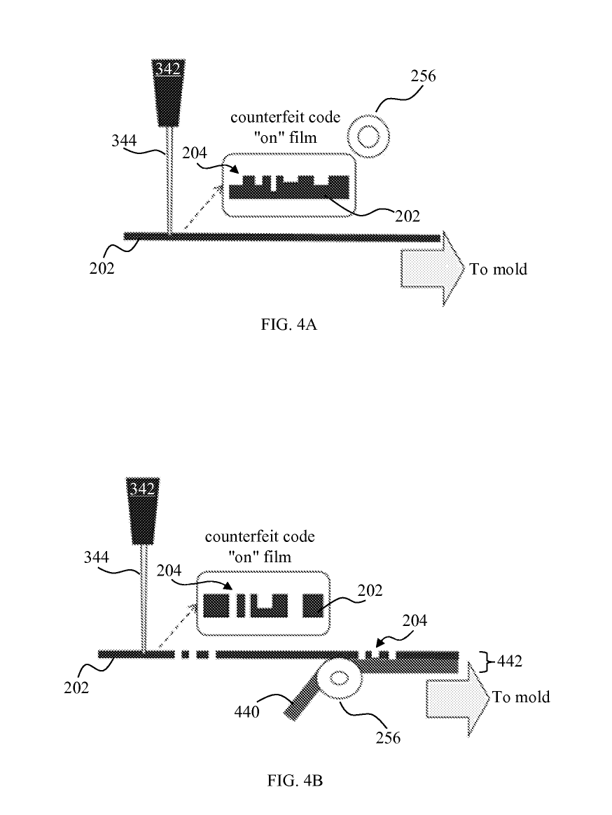

The counterfeit “code” design, corresponding to the mold pattern 204, may be created using a computer. There may be a high variability in the counterfeit code to be provided. As shown in FIG. 3, the film pattern 204 may be drilled into the film 202. Alternatively or additionally, the mold pattern 204 may be engraved into the film 202. By designing the film pattern 204, the code or surface pattern formed after imprinting on the package mold may be two-dimensional (2D) and/or three-dimensional (3D). As shown in FIG. 3, the film 202 may be a firm structure having at least one protrusion 206 and/or at least one recess 208. The (lasered) film 202 may then be used directly, as shown in FIG. 4A, or may be attached to a second film 440, as shown in FIG. 4B. Referring to FIG. 4A, a single film 202 has a film pattern or imprint 204 created by the laser 342 partially through the film 202. Referring to FIG. 4B, a first film 202 with a film pattern or imprint 204 created by the laser 342 entirely through the film 202 may be attached to a second film 440 to form a bi-layer film (or film structure) 442. The single film 202 of FIG. 4A or the bi-layer film 442 of FIG. 4B may then be used as the film-assist material during molding.

Laser on film may allow the process of various embodiments to use laser to quickly create the needed wide variety of complex (and unique) patterns that may be generated, for example by the counterfeit code generation system/program. Further, laser on film may be an “easy” integration into existing industry (film-assisted) molding processes. For example, it may be an additional module integrated right before the molding process.

Referring back to FIG. 3, a molding process 300 may then be carried out using the film structure 202, produced from the procedure 340. The molding process 300 may correspond to a code transfer process to a package mold. During the molding process 300, an electronic circuit 331 having a chip 332 provided on a leadframe 330 with wires 334 electrically coupling the chip 332 and the leadframe 330 may be provided in the cavity 258 between the upper molding portion 252 and the lower molding portion 254. The upper molding portion 252 and the lower molding portion 254 may be moved towards each other to secure the electronic circuit 331 within the cavity 258 and seal the cavity 258. A molding material 321 may then be provided within the cavity 258 in contact with the films 201, 202 as well as the film pattern 204 formed on the film 202. As shown in FIG. 3, the (lasered) film 202 faces the mold material 321. The molding material 321 may then be processed, for example heated and cured to form a mold encapsulating the electronic circuit 331. As a result, the “mark” design or film pattern 204 may be “transferred” into the resulting package mold, which may be shown as variation in the physical surface topography of the mold. Therefore, an integrated circuit (e.g. a semiconductor package) 320 may be formed, with a package mold or molding structure 322 encapsulating the electronic circuit 331 with its leadframe 330 exposed or protruding out of the package mold 322. As shown in FIG. 3, the molding structure 322 may have a flat, planar surface on the top side 333a conforming to the surface shape of the film 201, and an opposite surface on the bottom side 333b having an imprinted mark or surface pattern 328 formed conforming to the shape of the film structure 202.

FIGS. 5A and 5B show images of examples of film structures, according to various embodiments. Thick films 502a, 502b were used and the laser was adjusted not to fully penetrate the films 502a, 502b. As shown in FIGS. 5A and 5B, features (as shown within the dashed boxes) of the film patterns may be formed with different widths. The features of the film patterns were formed at the same laser depth penetration on the films 502a, 502b. As may be observed in FIGS. 5A and 5B, within each rectangle, at the unit-level, the film pattern may include a highly variable and possibly unique surface topology or morphology (e.g., rough surface) of the imprinted surface. Further, respective rectangular film patterns may be differently patterned, for example having different widths and/or surface roughness. A set or combination of differently patterned “rectangular” patterns (as shown within the white dashed boxes) may be provided, thereby increasing the variability of the entire film surface pattern. Such a set or combination of unit-level patterns may define a component-level film pattern. For example, the number and/or arrangement of the unit-level patterns may define a component-level film pattern. Further, such a set or combination may be a system-level generated pattern, for example, based on the system-level approach to be described below, by utilising the plurality of different coded patterns provided in a database or a server.

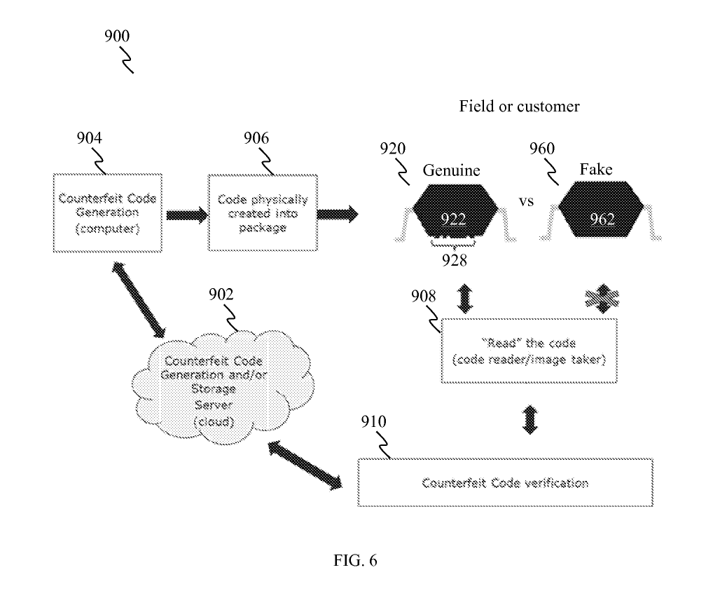

Various embodiments may further provide a system-level approach. For example, at the system-level, a code generation, storage and verification system against the component imprinted code may be provided, as shown in FIG. 6.

FIG. 6 shows a schematic view of a system-level procedure 900, according to various embodiments, illustrating for example how the unit-level and/or the component-level as described above may work with a verification system, as may be applied in the field or with customer(s). For the system-level approach 900, a counterfeit code generation and/or storage database or server 902, which for example may be cloud-based, may be provided. At 904, a counterfeit code may be generated, for example by a computer in cooperation with the server 902. As a non-limiting example, the counterfeit code may be determined or generated based on a plurality of different coded patterns provided in the server 902. As part of the manufacturing process at the component-level, at 906, the code may be physically created into an integrated circuit, for example using any methods as described above.

In the field or with a customer, an integrated circuit (e.g. a semiconductor package) may then be checked. As examples, a package 920 including a surface pattern or counterfeit code 928 formed onto the mold 922 of the package 920, and a package 960 having a mold 962 may be used for verification. At 908, a code reader or an image taker may be used to read the molds 922, 962.

At 910, verification of the counterfeit code may be carried out, against the counterfeit code server 902, so as to determine whether an integrated circuit may be genuine or fake. When the package 920 having an imprinted code 928 is checked and verified, where the imprinted code 928 and product marking match those in the database or server 902, the package 920 is verified and determined as a genuine package. When the package 960 without any imprint code is checked, the package 960 is determined as a counterfeit or fake package. Also, when a package with a non-genuine imprinted code is checked, where the imprinted code and product marking is not verified to be matched to those in the database or server 902, the package is determined as a counterfeit or fake package.

In various embodiments, a reader that may take or read surface topologies may be provided for reading the surface patterns or codes formed. For example, the reader or reader system may use “surface topology” as a “code”.

Various embodiments may also provide a package with thermal dissipation (element) and method for forming the same. In various embodiments, a thermally conductive material (or a thermal dissipation element), which may be a metal element, may be “suspended” on the mold compound or molding structure, meaning that it may not be in direct contact with the chip and/or the substrate of the chip. Various embodiments may provide heat dissipation improvement.

Various embodiments may employ film assisted molding to attach or embed one or more package elements, for example thermally conductive material or heat spreader(s), during assembly.

In various embodiments, a heat dissipating element (metal) may be provided to an integrated circuit, where the heat dissipating element may be “floating” or “suspended”, meaning that the heat dissipating element may be exposed on the ambient side and embedded on the package mold side, and the heat dissipating element may not need to be in contact or direct contact with the chip (or electronic circuit) or the substrate. This may mean that there may be no interaction between the leadframe, chip, die or wire bond with the heat sink or heat dissipating element. This may support the trend towards smaller packages additional substrate space may not be required, for example, for attachment of the heat dissipating element. Further, there may be a potential cost reduction and/or a faster assembly process compared to having a separate heat element attachment process which requires additional adhesive material cost and curing step. In various embodiments, the heat dissipating element may be applied to multiple sides of the mold of an integrated circuit. Package marking may be directly applied to the heat metal element, before molding, as a possible cost reduction. The heat sink may be applied in any or all directions or sides of the package. The heat sink may be in any desired shape and/or size. The heat sink may be applied on any types of packages. Further, replacement of encapsulation material with the heat sink may improve reliability, for example protection from moisture.

In various embodiments, the thermally conductive material or heat dissipating element attachment may be carried out at or during molding, for example using a modified film assisted molding process. In the resulting integrated circuit or package manufactured, the heat thermally conductive material may be “floating”—exposed on the ambient side and embedded on the package side without need for direct contact to the chip and/or substrate.

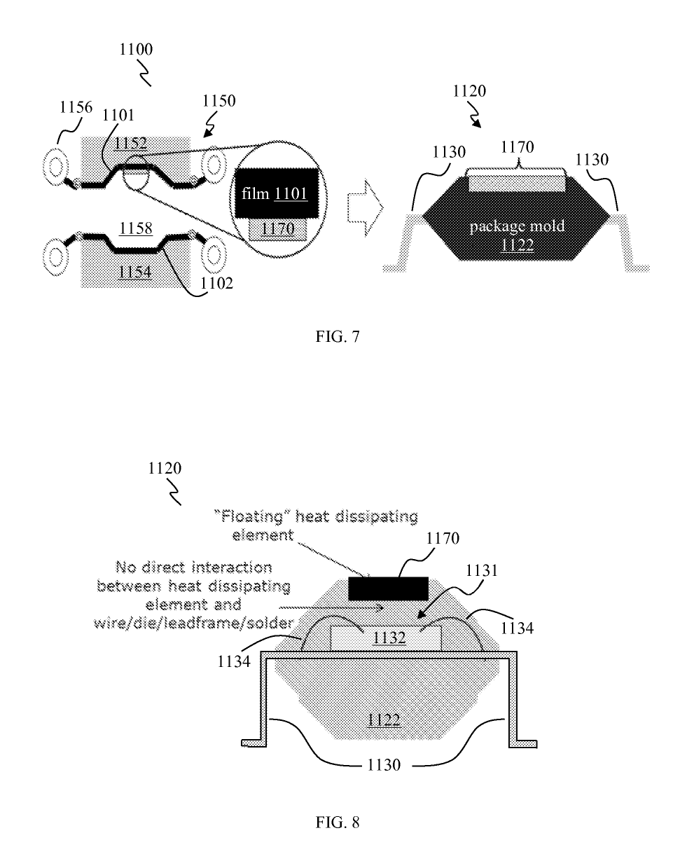

FIG. 7 shows a schematic view of a method 1100 for manufacturing an integrated circuit, according to various embodiments, illustrating an integrated attachment process using film assisted molding (FAM) where the attachment of a thermal element into an integrated circuit is integrated at molding using film assisted molding (FAM) technology.

As shown in FIG. 7, a package mold tool or apparatus 1150 may be used, which may include a molding housing including an upper molding portion 1152 and a lower molding portion 1154. A pair of films may be provided to the package mold tool 1150, including an upper film 1101 provided to the upper molding portion 1152 and a lower film 1102 provided to the lower molding portion 1154. The package mold tool 1150 may include a transportation system, including a plurality of rollers, for example as represented by 1156 for one roller for moving the films 1101, 1102. As shown in FIG. 7, as a non-limiting example, a thermally conductive material or a heat dissipating element (e.g. copper, aluminium) 1170 may be provided to or attached to the upper film 1101. During manufaturing, an electronic circuit (not shown) may be provided in between the upper molding portion 1152 and the lower molding portion 1154, which may then be moved towards each other to define a cavity or chamber 1158 and secure the electronic circuit in the cavity 1158. The cavity 1158 may be sealed and a molding material (not shown) may then be provided within the cavity 1158. The molding material may be in contact with the films 1101, 1102 and the thermally conductive material 1170. The molding material may then be processed, for example heated and cured to form a mold encapsulating the electronic circuit. It should be appreciated that a thermally conductive material may be provided to the lower film 1102, alternative to or in addition to, the thermally conductive material 1170 of the upper film 1101.

As a result, as shown in FIGS. 7 and 8, an integrated circuit 1120 may be formed, with a package mold 1122 encapsulating the electronic circuit with its leadframe 1130 exposed or protruding out of the package mold 1122, and a “floating” thermally conductive material or heat spreader 1170 embedded in the mold 1122. The thermally conductive material 1170 may be exposed on the ambient side and embedded on the package side. The thermally conductive material 1170 may have no direct contact with the die or chip 1132, wire 1134, leadframe 1130 or substrate of the electronic circuit 1131. Further, no additional adhesive to the leadframe 1130 and/or substrate is required.

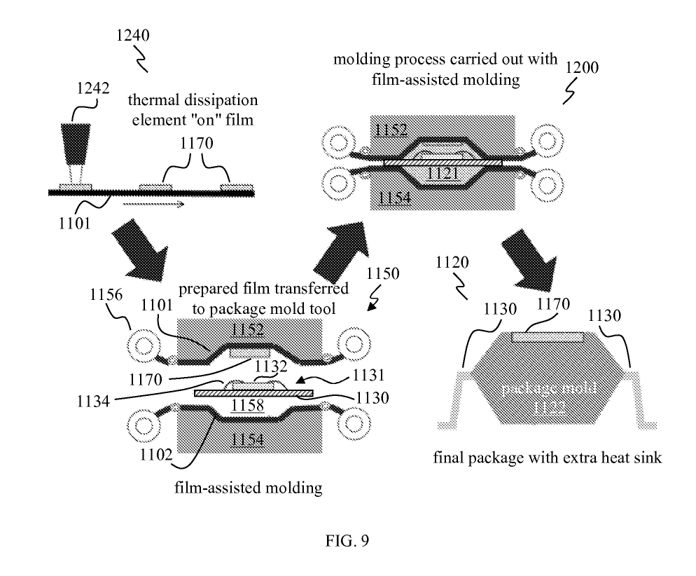

FIG. 9 shows a schematic view of a method for manufacturing an integrated circuit, according to various embodiments, illustrating a method or process of attachment of a thermally conductive material or heat dissipating element. The method may include a pre-molding procedure 1240 corresponding to a process of thermal conducting material creation and placement to film. During the procedure 1240, thermally conductive materials or heat dissipation elements (e.g. copper) 1170, for example in the form of metal foils, particles or solid elements (e.g. metal blocks) may be added or provided onto a film 1101. For example, a tool 1242 may be used to provide the thermally conductive materials 1170. The prepared film 1101 with a thermally conductive material 1170 may then be transferred to package mold tool 1150 by means of the rollers 1156.

For preparation of the molding process to be carried out, an electronic circuit 1131 having a chip 1132 provided on a leadframe 1130 with wires 1134 electrically coupling the chip 1132 and the leadframe 1130 may be provided in the cavity 1158 between the upper molding portion 1152 and the lower molding portion 1154. During the molding process 1200, the upper molding portion 1152 and the lower molding portion 1154 may be moved towards each other to secure the electronic circuit 1131 within the cavity 1158 and seal the cavity 1158. A molding material 1121 may then be provided within the cavity 1158 in contact with the films 1101, 1102 as well as the thermally conductive material 1170 formed on the film 1101. As shown in FIG. 9, the thermally conductive material 1170 faces the mold material 1121. The molding material 1121 may then be processed, for example heated and cured to form a mold encapsulating the electronic circuit 1131. As a result, the thermally conductive material or heat dissipating element 1170 may be at least partially embedded into the resulting package mold. Therefore, an integrated circuit 1120 may be formed, with a package mold 1122 encapsulating the electronic circuit 1131 with its leadframe 1130 exposed or protruding out of the package mold 1122.

FIGS. 10A and 10B show schematic views of different methods for forming a thermally conductive material to a film, according to various embodiments, illustrating non-limiting examples of metal to film preparation. As shown in FIG. 1 OA, a tool (e.g. a deposition tool) 1342 may be used to provide a thermally conductive material or heat dissipation element 1170 onto a film 1101, for direct placement of the thermally conductive material 1170 on a single film 1101. Referring to FIG. 10B, a laser 1344 may be used to emit a beam or radiation 1346 to create openings or holes 1347 in the film 1101. The film 1101 may then be attached to a second film 1340 to form a bi-layer film 1341. A tool (e.g. a deposition tool) 1348 may then be used to provide thermal element material 1349 to form a thermally conductive material 1170 within the hole 1347 created in the film 1101. The single film 1101 of FIG. 10A or the bi-layer film 1341 of FIG. 10B may then be provided to a package mold tool.

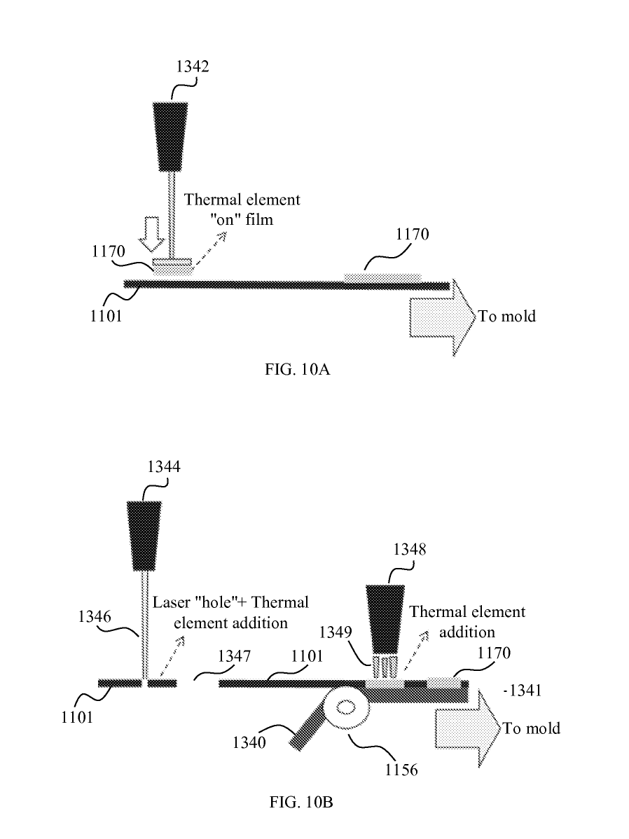

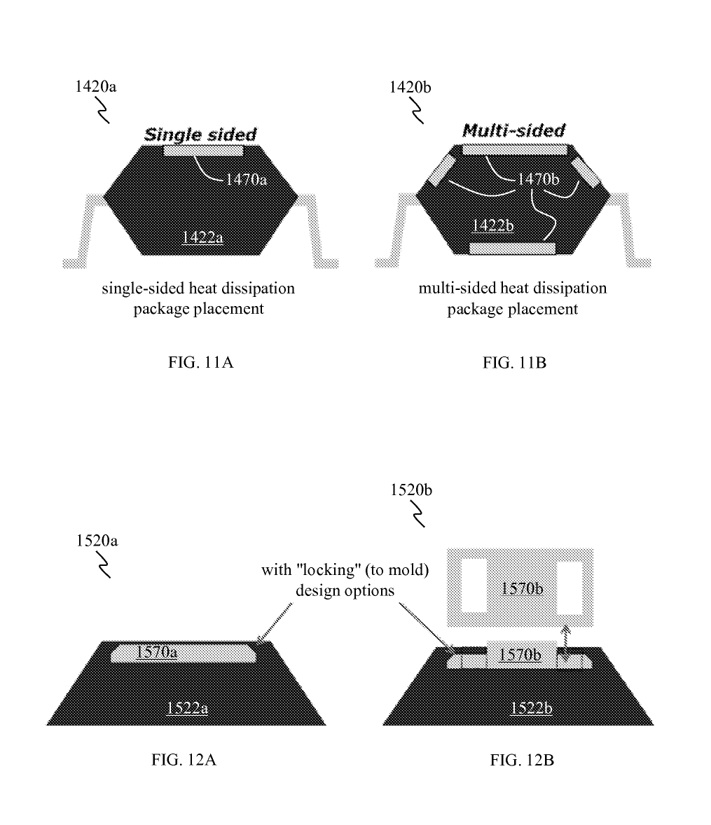

FIGS. 11A and 11B show schematic views of different integrated circuits 1420a, 1420b that may be formed, according to various embodiments. Referring to FIG. 11A, an integrated circuit 1420a with a thermally conductive material or heat dissipation element 1470a embedded on one side of the mold or molding structure 1422a may be formed to provide a single-sided heat dissipation package 1420a. Referring to FIG. 11B, an integrated circuit 1420b with thermally conductive materials 1470b embedded on multiple sides of the mold 1422b may be formed to provide a multi-sided heat dissipation package 1420b.

FIGS. 12A and 12B show schematic views of different integrated circuits or integrated circuit packages 1520a, 1520b that may be formed, according to various embodiments, illustrating one or more material elements such as thermal dissipation elements 1570a 1570b in the packages 1520a, 1520b, with “locks” or “locking” design options or features that may secure the thermally conductive materials or thermal dissipation elements 1570a, 1570b to the molds 1522a, 1522b so as to improve mechanical locking between the thermally conductive materials 1570a, 1570b and the mold compounds 1522a, 1522b.

It should be appreciated that various embodiments as described above may be combined. For example, various embodiments described in the context of an integrated circuit having a surface pattern imprinted into the mold of the integrated circuit and the method thereof may be combined with various embodiments described in the context of an integrated circuit having a thermally conductive material embedded into the mold of the integrated circuit and the method thereof, and vice versa.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of manufacturing an integrated circuit, the method comprising:
providing a film structure having at least one of at least one recess or at least one protrusion; and
carrying out a film assisted molding process using the film structure to mold an electronic circuit, thereby forming a molding structure including a surface pattern in accordance with the film structure.

2. The method as claimed in claim 1, further comprising:
patterning a film to form the film structure.

3. The method as claimed in claim 1, wherein the at least one of at least one recess or at least one protrusion of the film structure faces the mold during the film assisted molding process.

4. The method as claimed in claim 2, wherein patterning the film comprises laser processing the film to pattern the film.

5. The method as claimed in claim 2, further comprising:
determining a mold pattern from a plurality of different coded patterns provided in a database; and
patterning the film in accordance with the determined mold pattern.

6. The method as claimed in claim 1, further comprising:
placing thermally conductive material over a surface of a film; and
transferring the thermally conductive material into the molding structure.

7. The method as claimed in claim 6,
wherein the thermally conductive material is pressed or embedded into the mold material to form the molding structure.

8. The method as claimed in claim 6,
wherein at least one surface of the thermally conductive material formed in the molding structure is exposed.

9. The method as claimed in claim 6,
wherein the thermally conductive material comprises metal.

10. The method as claimed in claim 6,
wherein the thermally conductive material is formed by a metal block.

11. The method as claimed in claim 6, wherein the thermally conductive material has a surface marking.

12. The method as claimed in claim 6, wherein the thermally conductive material is not in contact with the electronic circuit or a substrate of the electronic circuit.

13. The method as claimed in claim 6, wherein the entire thermally conductive material is arranged spaced apart from the electronic circuit or a substrate of the electronic circuit.

14. An integrated circuit, comprising:
an electronic circuit; and
a mold encapsulating the electronic circuit,
wherein the mold comprises an outer surface pattern imprinted into the mold.

15. The integrated circuit as claimed in claim 14, wherein the outer surface pattern has at least one of at least one recess or at least one protrusion.

16. The integrated circuit as claimed in claim 14, further comprising:
a thermally conductive material embedded into the mold.

17. The integrated circuit as claimed in claim 16,
wherein at least one surface of the thermally conductive material formed in the mold is exposed.

18. The integrated circuit as claimed in claim 16,
wherein the thermally conductive material comprises metal.

19. The integrated circuit as claimed in claim 16,
wherein the thermally conductive material is a metal block.

20. The integrated circuit as claimed in claim 16, wherein the thermally conductive material has a surface marking.

21. The integrated circuit as claimed in claim 16, wherein the thermally conductive material is not in contact with the electronic circuit or a substrate of the electronic circuit.

22. The integrated circuit as claimed in claim 16, wherein the entire thermally conductive material is arranged spaced apart from the electronic circuit or a substrate of the electronic circuit.

23. A device for forming an integrated circuit, the device comprising:
a film structure having at least one of at least one recess or at least one protrusion; and
an apparatus for forming an integrated circuit, the apparatus configured to carry out a film assisted molding process using the film structure to mold an electronic circuit, thereby forming a molding structure including a surface pattern in accordance with the film structure.

24. The device as claimed in claim 23, further comprising a pattern forming device configured to pattern a film to form the film structure.

25. The device as claimed in claim 24, further comprising:
a database comprising a plurality of different coded patterns; and
a circuit for determining a mold pattern from the plurality of different coded patterns,
wherein the pattern forming device is configured to pattern the film in accordance with the determined mold pattern.

26. The device as claimed in claim 23, further comprising a film having a thermally conductive material over a surface of the film,
wherein the apparatus is further configured to transfer the thermally conductive material into the molding structure.

27. The device as claimed in claim 26, wherein the apparatus is configured to press the thermally conductive material into the mold material to form the molding structure.

28. The device as claimed in claim 26,
wherein at least one surface of the thermally conductive material formed in the molding structure is exposed.

29. The device as claimed in claim 26,
wherein the thermally conductive material comprises metal.

30. The device as claimed in claim 26,
wherein the thermally conductive material is formed by a metal block.

31. A verification system for an integrated circuit, the system comprising:
a database comprising a plurality of different coded patterns;
a reader for reading a mold of an integrated circuit to determine presence of a surface pattern on the mold; and
a verification circuit configured to verify the surface pattern, if present on the mold, against the plurality of different coded patterns in the database,
wherein the verification circuit is further configured to generate a positive indication signal if the surface pattern is verified to be determined from the plurality of different coded patterns, and to generate a negative indication signal if the surface pattern is verified to be not determined from the plurality of different coded patterns or if a surface pattern is not present on the mold.
